(19) United States
(12) Patent Application Publication
(10) Pub. No.: US 2017/0372792 A1
(43) Pub. Date: Dec. 28, 2017

(54) TEST APPARATUS, MEMORY TEST SYSTEM, AND TEST METHOD

(71) Applicant: SK hynix Inc., Icheon-si (KR)

(72) Inventors: Hak Song KIM, Seoul (KR); Chang Yong AHN, Seoul (KR)

(73) Assignee: SK hynix Inc., Icheon-si (KR)

(21) Appl. No.: 15/473,987

(22) Filed: Mar. 30, 2017

(30) Foreign Application Priority Data
Jun. 22, 2016 (KR) 1020160078080

(51) Int. Cl. G11C 29/08; G06F 11/25

(52) U.S. Cl. CPC G11C 29/08; G06F 11/25

(57) ABSTRACT

A memory test system may include a memory apparatus and a test apparatus. The test apparatus may be configured to generate a code distribution of noble cells. The test apparatus may be configured to generate a mass data code distribution and a test result based on the code distribution of noble cells.

### CROSS-REFERENCES TO RELATED APPLICATION

The present application claims priority under 35 U.S.C. §119(a) to Korean application number 10-2016-0078080, filed on Jun. 22, 2016 in the Korean Intellectual Property Office, which is incorporated herein by reference in its entirety.

### BACKGROUND

### 1. Technical Field

Various embodiments may generally relate to a semiconductor technology, and, more particularly, to a test apparatus, memory test system, and a test method.

### 2. Related Art

In a computer system, a dynamic random access memory (DRAM) is widely used because the DRAM is capable of processing a great amount of data at rapid operation speeds. However, the DRAM is a volatile memory apparatus and therefore has a fault whereby stored data is lost when power is abruptly cut off. In order to overcome this limitation of the DRAM, a FLASH memory apparatus, which is a nonvolatile memory apparatus, has been suggested.

The FLASH memory apparatus is capable of maintaining stored data even when power is abruptly cut off since the FLASH memory apparatus stores data by trapping charges through a floating gate. The FLASH memory apparatus has an advantage of processing a great amount of data but has relatively slower operation speeds than the DRAM apparatus and does not provide random access.

In order to avoid the shortcomings of the DRAM apparatus and the FLASH memory apparatus, next generation memory apparatuses, which have fast operation speeds and are non-volatile, have been suggested. Examples of the next generation memory apparatuses suggested so far may consist of a Phase change RAM (PRAM), a Magnetic RAM (MRAM), a Resistive RAM (RRAM), a Ferroelectric RAM (FRAM) and a Spin Torque Transfer RAM (STTMRAM). Most types of next generation memory apparatuses have similar circuit structures to the DRAM apparatus with a memory cell, in which new materials are being substituted for a capacitor. Even though the next generation memory apparatuses are non-volatile, data stored in the next generation memory apparatuses may be lost as time passes due to characteristics of the materials included in the memory cell. Particularly, the PRAM and RRAM may lose data stored therein due to a change of resistance values by the drift phenomenon. Therefore, a test may be performed for measuring a retention time of a memory cell.

### SUMMARY

In an embodiment, a memory test system may be provided. In an embodiment, a method may be provided. In an embodiment, a test apparatus may be provided. The test apparatus may be configured to generate a code distribution of noble cells. The test apparatus may be configured to generate a mass data code distribution and a test result based on the code distribution of noble cells.

### BRIEF DESCRIPTION OF THE DRAWINGS

FIG. 1 is a block diagram illustrating a configuration of a memory test system in accordance with an embodiment.

FIGS. 2 and 3 are flow chart illustrating an operation of a memory test system in accordance with an embodiment.

FIG. 4 is a diagram illustrating a representation of an example of a result of an operation of a memory test system in accordance with an embodiment.

### DETAILED DESCRIPTION

Hereinafter, a semiconductor apparatus according to the present invention will be described below with reference to the accompanying drawings through exemplary embodiments.

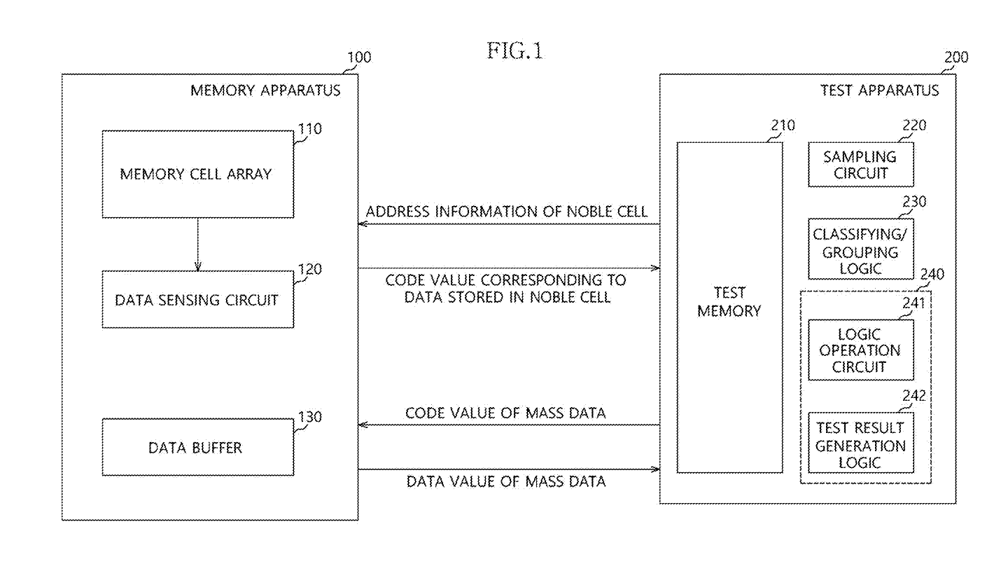

FIG. 1 is a block diagram illustrating a configuration of a memory test system in accordance with an embodiment. Referring to FIG. 1, the memory test system may include a memory apparatus 100 and a test apparatus 200. The test apparatus 200 may include a next generation memory apparatus such as a Phase change RAM (PRAM), a Magnetic RAM (MRAM), a Resistive RAM (RRAM), a Ferroelectric RAM (FRAM), a Spin Torque Transfer RAM (STTMRAM) and so forth. However, the type of the memory apparatus 100 will not be limited and memory apparatus 100 may be any memory apparatus including a memory cell capable of storing multi-level data. The test apparatus 200 may be provided for a test of the memory apparatus 100. The test apparatus 200 may include a circuit or a logic having an algorithm or a program capable of testing various functions of the memory apparatus 100. For example, the test apparatus 200 may include a computer device, a test board or test equipment such as automatic test equipment (ATE).

Referring to FIG. 1, the memory apparatus 100 may include a memory cell array 110, a data sensing circuit 120 and a data buffer 130. The memory cell array 110 may include a plurality of memory cells, and a plurality of bit lines and a plurality of word lines respectively coupled to the plurality of memory cells. The plurality of bit lines and the plurality of word lines may be selected on the basis of an address. When particular bit line and word line are selected, a memory cell of a particular location may be accessed. The data sensing circuit 120 may sense data stored in a memory cell selected among the memory cells of the memory cell array 110. In an embodiment, the memory cell may be a multi-level cell capable of storing multi-level data. For example, the memory cell may store 2-bit information, and data that the memory cell can store may include ‘0, 0’, ‘0, 1’, ‘1, 0’ and ‘1, 1’. For example, the memory cell may store 3-bit information, and data that the memory cell can store may include ‘0, 0, 0’, ‘0, 0, 1’, ‘0, 1, 0’, ‘0, 1, 1’, ‘1, 0, 0’, ‘1, 0, 1’, ‘1, 1, 0’ and ‘1, 1, 1’. The data sensing circuit 120 may include an analogue-to-digital converter ADC configured to sense a multi-level data. The data sensing circuit 120 may generate a code value by sensing data stored in the memory cell. For example, the data sensing circuit 120 may convert a current or a voltage, which is output from the memory cell, into a digital code. The data buffer 130 may generate a data value based on the code value generated by the data sensing circuit 120. The data value may be a value corresponding to the multi-level data. The data buffer 130 may receive a code value corresponding to data stored in the memory cell from the data sensing circuit 120 during a normal operation. The data buffer 130 may receive a code value corresponding to data stored in the memory cell from a test memory 210, which will be described later, during a test operation. The normal operation may be a read operation performed by the memory apparatus 100, and the test operation may be performed by the test apparatus 200 for testing the memory apparatus 100.

The test apparatus 200 may include a test memory 210, a sampling circuit 220, a classifying/grouping logic 230 and a test logic 240. The test memory 210 may be a data storage medium such as a register, and may store all information related to a test to the memory apparatus 100. The test memory 210 may store information provided from the memory apparatus 100, and may store information generated by an internal circuit of the test apparatus 200.

The sampling circuit 220 may select noble cells. The noble cells may include an arbitrary number of memory cells among the plurality of memory cells included in the memory cell array 110. The number of noble memory cells may be changed arbitrarily. For example, the number of noble cells may be 100, 1000 or 10000. The sampling circuit 220 may select the noble cells, and may store address information for accessing the noble cells into the test memory 210. As time passes, the sampling circuit 220 may store code values corresponding to data stored in the noble cells into the test memory 210. For example, the sampling circuit 220 may store code values corresponding to data, which are stored in the noble cells at a first point of time, into the test memory 210, may store code values corresponding to data, which are stored in the noble cells at a second point of time, into the test memory 210, and may store code values corresponding to data, which are stored in the noble cells at a third point of time, into the test memory 210. The first to third points of time may be after a point of time when the data are stored into the noble cells. Further, the first to third points of time may be arbitrary points of time. Although not limited, the first point of time may be ten minutes, the second point of time may be an hour, and the third point of time may be a single day.

The classifying/grouping logic 230 may generate a code distribution of noble cells by classifying and grouping the code values stored in the test memory 210. The sampling circuit 220 may generate the code distribution of noble cells by binning each of the code values stored in the test memory 210 at the first to third points of time. The noble cells may be arbitrarily selected from the plurality of memory cells included in the memory cell array 110, and data stored in the noble cells may be different from one another. For example, when the memory cell stores 2-bit information and a number of noble cells is 100, a number of noble cells storing data of ‘0, 0’ may be 20, a number of noble cells storing data of ‘0, 1’ may be 30, a number of noble cells storing data of ‘1, 0’ may be 40, and a number of noble cells storing data of ‘1, 1’ may be 10. The classifying/grouping logic 230 may generate the code distribution of noble cells by classifying and grouping the code values according to threshold values of the code value. A number of the threshold values may be 3. For example, a code value under a first threshold value may be classified into a code value corresponding to data of ‘0, 0’, and a code value over the first threshold value and under a second threshold value may be classified into a code value corresponding to data of ‘0, 1’. For example, a code value over the second threshold value and under a third threshold value may be classified into a code value corresponding to data of ‘1, 0’, and a code value over the third threshold value may be classified into a code value corresponding to data of ‘1, 1’.

The test logic 240 may generate drift coefficients based on the code distribution of noble cells. The drift coefficient may be a variable or characteristic change of memory cell as time passes due to characteristics of materials included in the memory cell. For example, when the memory cell includes a phase-change material or a variable resistive material, the drift coefficient may be information that a resistance value of the memory cell changes as time passes, and include an average, a variance, a change gradient and so forth. The test logic 240 may generate a mass data code distribution from the code distribution of noble cells by reflecting the drift coefficients. The test logic 240 may generate the mass data code distribution by performing an extended calculation operation to the code distribution of noble cells based on the drift coefficients. The mass data code distribution may include code values corresponding to a number of all memory cells substantially included in the memory cell array 110.

The test logic 240 may store the mass data code distribution into the test memory 210. Further, the test logic 240 may control the test memory 210 to provide the data buffer 130 with the code values, an amount of which the data buffer 130 can process at a time, included in the mass data code distribution. The test logic 240 and the test memory 210 may sequentially provide all of the code values included in the mass data code distribution to the data buffer 130. The data buffer 130 may convert the code values provided from the test memory 210 into data values, and may provide the data values to the test memory 210. The data values converted by the data buffer 130 may be stored in the test memory 210, and the test logic 240 may generate a mass data distribution from the data values. The test logic 240 may generate a test result from the mass data distribution.

The test logic 240 may include a logic operation circuit 241 and a test result generation logic 242. The logic operation circuit 241 may generate the drift coefficients from the code distribution of noble cells, and may generate the mass data code distribution from the code distribution of noble cells by reflecting the drift coefficients. The test result generation logic 242 may generate the test result based on the mass data distribution. In an embodiment of the present disclosure, the test result may be related to a retention time of a memory cell. The retention time of memory cell may be a time segment, during which a value of data stored in a memory cell is changed to other value due to the drift phenomenon as time passes.

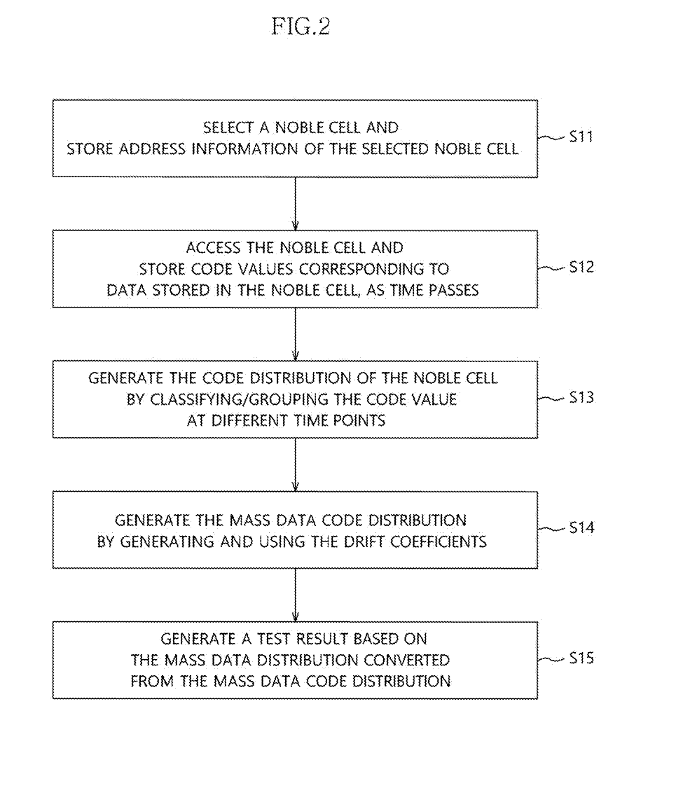

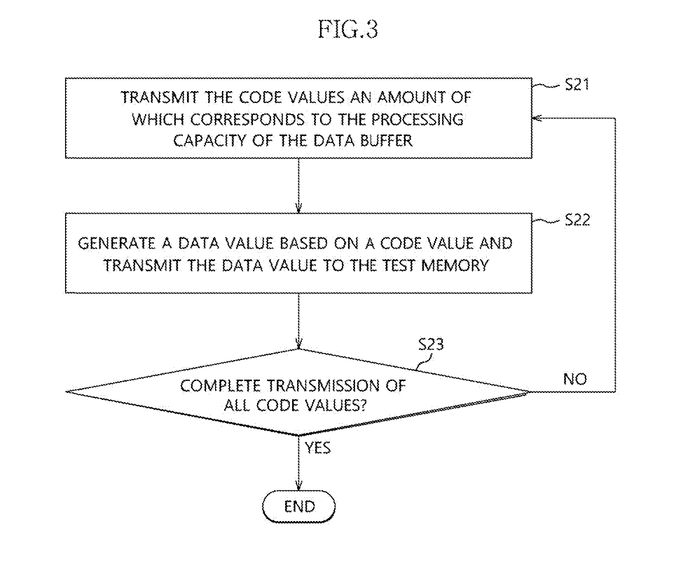

FIGS. 2 and 3 are flow chart illustrating a representation of an example of an operation of a memory test system in accordance with an embodiment of the present disclosure. FIG. 2 illustrates a software operation of the memory test system, and FIG. 3 illustrates a hardware operation of the memory test system. Described hereinafter with reference with FIGS. 1 to 3 will be a test method of the memory test system in accordance with an embodiment of the present disclosure. Since the memory apparatus 100 includes a great number of memory cells, it is substantially impossible to measure the retention time of each of the memory cells. Also, due to uncertainty of the retention time, it takes very long time even to measure the retention time of a particular memory cell and it is hard to perform a precise test operation of the particular memory cell. In an embodiment, the test apparatus 200 may select noble cells among the plurality of memory cells included in the memory apparatus 100. The sampling circuit 220 may select noble cells, and may store information for accessing the selected noble cells (e.g., address information) into the test memory 210 (S11). As time passes, the sampling circuit 220 may access the noble cells at each of the first to third points of time. The data sensing circuit 120 may sense currents or voltages output from the noble cells, and provide code values corresponding to data stored in the noble cells to the test memory 210. The test memory 210 may store the code values (S12).

The classifying/grouping logic 230 may generate the code distribution of the noble cells by classifying and grouping (classifying/grouping) the code values at each of the first to third points of time (S13). The logic operation circuit 241 may generate the drift coefficients by analysing the code distribution of noble cells at each of the first to third points of time. Further, the logic operation circuit 241 may generate the mass data code distribution by reflecting the drift coefficients (S14).

The test result generation logic 242 may generate the test result based on the mass data distribution converted from the mass data code distribution. The logic operation circuit 241 may generate the mass data code distribution, to which the extended calculation operation is performed, by reflecting the drift coefficients to the code distribution of noble cells generated at each of the first to third points of time. Therefore, the mass data distribution may include a distribution of data values of a greater number of memory cells than a number of the noble cells after the third point of time. Here, a time segment during which the distribution of data values changes may be detected as the retention time (S15). The mass data distribution may include a distribution of data values at time points after the third point of time, the test result generation logic 242 may detect a time when any one among the data values of the mass data changes to a value different from a previous value, as the retention time.

The mass data distribution may be generated from the mass data code distribution through the hardware operation of the memory test system as illustrated in FIG. 3. The test logic 240 may generate the mass data code distribution and store the mass data code distribution into the test memory 210. The test logic 240 may provide the data buffer 130 with the code values, an amount of which corresponds to a processing capacity of the data buffer 130, that is, corresponds to an amount that the data buffer 130 can process at a time (S21). The data buffer 130 may convert the code values provided from the test logic 240 into data values, and may provide the converted data values to the test memory 210. The test memory 210 may store the data values. The test logic 240 may determine whether all the code values have been provided (S23). When all code values are not provided, the test logic 240 may provide again the data buffer 130 with the code values, an amount of which corresponds to the amount that the data buffer 130 can process at a time (S21). Steps S23, S21 and S22 may be repeated until all code values have been provided to the data buffer 130. When all code values have been provided to the data buffer 130 and the data values corresponding to all code values are generated and stored, the hardware operation may end.

In an embodiment of the present disclosure, the hardware operation may be internally performed by the test apparatus 200 without communication with the memory apparatus 100. In the above described embodiments, since the memory apparatus 100 may include the data buffer 130 in general, a scheme for utilizing the data buffer 130 may be provided. However, the data buffer 130 may be provided inside the test apparatus 200. For example, the data buffer 130 may be coupled between the logic operation circuit 241 and the test result generation logic 242.

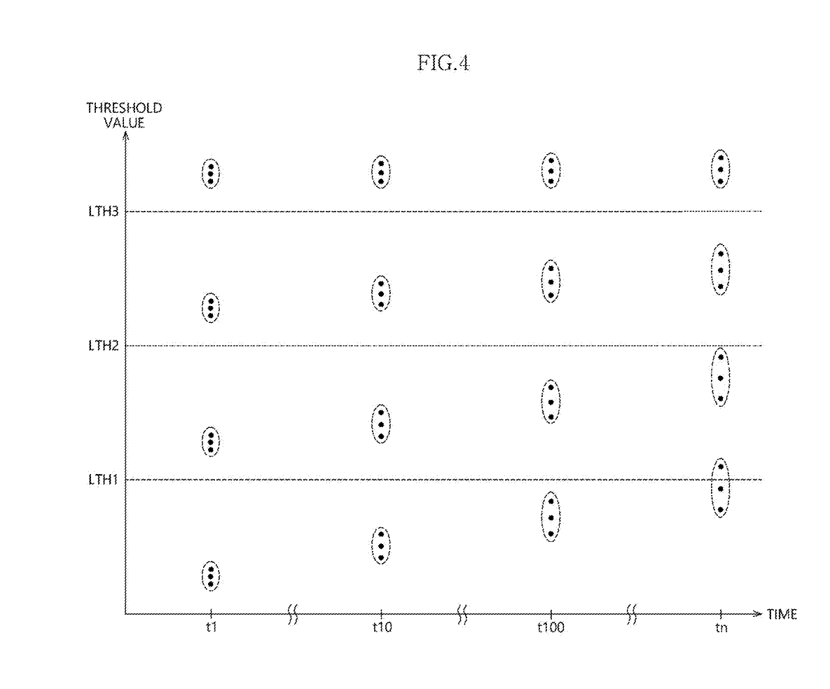

FIG. 4 is a diagram illustrating a representation of an example of a result of an operation of a memory test system in accordance with an embodiment of the present disclosure. The sampling circuit 220 may select the noble cells, and the code value corresponding to data stored in the noble cells at a first point t1 of time and may store the code values corresponding to the data stored in the noble cells in the test memory 210. The classifying/grouping logic 230 may generate the code distribution of noble cells at the first point t1 of time by classifying and grouping the code values. Referring to FIG. 4, the code distribution of noble cells is presented by dots. When the memory cell stores 2-bit information, a code value under a first threshold value LTH1 may be classified into a code value corresponding to data of ‘0, 0’, a code value over the first threshold value LTH1 and under a second threshold value LTH2 may be classified into a code value corresponding to data of ‘0, 1’, a code value over the second threshold value LTH2 and under a third threshold value LTH3 may be classified into a code value corresponding to data of ‘1, 0’, and a code value over the third threshold value LTH3 may be classified into a code value corresponding to data of ‘1, 1’.

At a second point t10 of time, the sampling circuit 220 may access the noble cells and the code values corresponding to the data stored in the noble cells may be stored in the test memory 210. The classifying/grouping logic 230 may generate the code distribution of noble cells at the second point t10 of time by classifying and grouping the code values. At a third point t100 of time, the sampling circuit 220 may access the noble cells and the code values corresponding to the data stored in the noble cells and the code values corresponding to the data stored in the noble cells may be stored in the test memory 210. The classifying/grouping logic 230 may generate the code distribution of noble cells at the third point t100 of time by classifying and grouping the code values.

The test logic 240 may generate the drift coefficients by analysing the code distributions of noble cells at the first to third points t1, t10 and t100 of time. The test logic 240 may generate the drift coefficients based on changes of the code distributions of noble cells at the first to third points t1, t10 and t100 of time. The test logic 240 may generate the mass data code distribution from the code distribution of noble cells by using the drift coefficients. Referring to FIG. 4, the mass data code distribution is represented by a dotted circle. The test logic 240 may generate the test result by analysing the mass data code distribution. Referring to FIG. 4, at an n-th point tn of time, a part of the mass data code distribution under the first threshold value LTH1 is changed to cross over the first threshold value LTH1. Therefore, the test logic 240 may generate the test result by determining the n-th point tn of time as the retention time. Also, the test logic 240 may acquire the retention time by converting the mass data code distribution into the mass data distribution through signal transmission with the data buffer 130.

While certain embodiments have been described above, it will be understood to those skilled in the art that the embodiments described are by way of example only. Accordingly, the memory test system and test method should not be limited based on the described embodiments. Rather, the memory test system and test method described herein should only be limited in light of the claims that follow when taken in conjunction with the above description and accompanying drawings.

What is claimed is:

1. A memory test system comprising:
a memory apparatus; and
a test apparatus,
wherein the test apparatus includes:
a sampling circuit configured to select noble cells, and access the noble cells as time passes;
a classifying and grouping (classifying/grouping) logic configured to generate a code distribution of noble cells by classifying and grouping code values corresponding to data stored in the noble cells; and
a test logic configured to generate drift coefficients based on the code distribution of noble cells, and generate a mass data code distribution and a test result based on the code distribution of noble cells.

2. The memory test system of claim 1, further comprising:
a test memory included in the test apparatus,
wherein the sampling circuit arbitrarily selects a predetermined number of memory cells in order to select the noble cells, and stores address information of the selected memory cells into the test memory.

3. The memory test system of claim 2, wherein the sampling circuit arbitrarily selects the predetermined number of memory cells from a plurality of memory cells included in the memory apparatus.

4. The memory test system of claim 1, further comprising:
a test memory included in the test apparatus,
wherein the sampling circuit stores the code values corresponding to the data stored in the noble cells into the test memory by accessing the noble cells at, at least two or more, different time points.

5. The memory test system of claim 1, wherein the test logic generates the drift coefficients based on the code distribution of noble cells.

6. The memory test system of claim 5, wherein the test logic generates the mass data code distribution by reflecting the drift coefficients into the code distribution of noble cells.

7. The memory test system of claim 1, further comprising:
a test memory included in the test apparatus,
wherein the memory apparatus further includes:
a data sensing circuit configured to generate the code values corresponding to the data stored in the noble cells; and
a data buffer configured to receive the code value provided from the test memory.

8. The memory test system of claim 7, wherein the data sensing circuit is an analogue-to-digital converter (ACD).

9. The memory test system of claim 7,
wherein the test logic includes:
a logic operation circuit configured to generate the mass data code distribution from the code distribution of noble cells, and store the mass data code distribution into the test memory; and
a test result generation logic configured to generate the test result based on a mass data distribution generated from the mass data code distribution.

10. The memory test system of claim 7, wherein the test logic provides the data buffer with the code values, an amount of which corresponds to a processing capacity of the data buffer, which is an amount that the data buffer can process at a time, and sequentially provides the data buffer with the code values corresponding to the mass data code distribution.

11. The memory test system of claim 10, further comprising:
a test memory included in the test apparatus,
wherein the data buffer provides the test memory with data values generated on the basis of the code values.

12. The memory test system of claim 1, wherein the test result is based on a retention time of a memory cell.

13. The memory test system of claim 12, wherein the retention time of the memory cell is a time segment, during which a value of data stored in the memory cell is changed to another value as time passes.

14. The memory test system of claim 13, wherein the memory cell is changed to the another value due to a drift phenomenon as the time passes.

15. The memory test system of claim 13, wherein the classifying/grouping logic is configured to generate the code distribution of the noble cells by classifying and grouping the code values corresponding to the data stored in the noble cells based on one or more threshold values.

16. A test apparatus comprising:
a classifying and grouping (classifying/grouping) logic configured to generate a code distribution of noble cells by classifying and grouping code values corresponding to data stored in the noble cells; and
a test logic configured to generate drift coefficients based on the code distribution of noble cells, and generate a mass data code distribution and a test result based on the code distribution of noble cells.

17. The test apparatus of claim 16, further comprising a sampling circuit configured to select noble cells, and access the noble cells as time passes.

18. A method of testing with a memory test system, the test method comprising:
selecting noble cells and storing address information of the selected noble cells;
accessing the noble cells and storing code values corresponding to data stored in the noble cells at predetermined time points;
generating a code distribution of the noble cells by classifying and grouping the code values at the predetermined time points;
generating a mass data code distribution by generating and using drift coefficients based on the code distribution of the noble cells; and
generating a test result based on mass data distribution converted from the mass data code distribution.

19. The test method of claim 18, wherein the noble cells are selected from among a plurality of memory cells included in a memory apparatus.

20. The test method of claim 18, wherein the classifying and grouping of the code values at the predetermined time points is based on predetermined threshold values.
